(19) United States
(12) Patent Application Publication
(10) Pub. No.: US 2025/0062131 A1
(43) Pub. Date: Feb. 20, 2025

(54) PLASMA ETCHING IN SEMICONDUCTOR PROCESSING

(71) Applicant: Applied Materials, Inc., Santa Clara, CA (US)

(72) Inventors: Hanbyul Jin, San Jose, CA (US); Sangjun Park, Fremont, CA (US); Menghui Li, Mountain View, CA (US); Xiawan Yang, San Jose, CA (US); Sunil Srinivasan, Pleasanton, CA (US); Meishen Liu, Sunnyvale, CA (US); Andrew Butler, Boise, ID (US); Qian Fu, Pleasanton, CA (US)

(73) Assignee: Applied Materials, Inc., Santa Clara, CA (US)

(21) Appl. No.: 18/234,685

(22) Filed: Aug. 16, 2023

(51) Int. Cl. H01L 21/308; H01L 21/02; H01L 21/3065; H01L 21/311

(52) U.S. Cl. CPC H01L 21/308; H01L 21/02164; H01L 21/02274; H01L 21/3065; H01L 21/311

(57) ABSTRACT

Methods of semiconductor processing may include forming plasma effluents of a plurality of precursors (e.g., an etchant precursor, an oxygen-containing precursor, and a silicon-and-fluorine-containing precursor like silicon tetrafluoride). The plasma effluents may then contact a silicon-containing material and a mask material on a substrate in a processing region of a semiconductor processing chamber. The mask material may have one or more apertures therein that allow the plasma effluents access to the silicon-containing material. Contacting the silicon-containing material and the mask material with the plasma effluents may cause (i) etching the silicon-containing material with the plasma effluents to form and/or deepen one or more features in the silicon-containing material and (ii) simultaneously etching the mask material and depositing a silicon-and-oxygen-containing material on the mask material with the plasma effluents.

### TECHNICAL FIELD

The present technology relates to methods and components for semiconductor processing. More specifically, the present technology relates to systems and methods for etching silicon-containing materials.

### BACKGROUND

Integrated circuits are made possible by processes that produce intricately patterned material layers on substrate surfaces. Producing patterned material on a substrate requires controlled methods for the removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. As a result of the diversity of materials, circuits, and processes, etch processes have been developed with a selectivity towards a variety of materials.

Etch processes may be termed wet or dry based on the materials used in the process. A wet HF etch preferentially removes silicon oxide over other dielectrics and materials. However, wet processes may have difficulty penetrating some constrained trenches and also may sometimes deform the remaining material. Dry etches produced in local plasmas formed within the substrate processing region can penetrate more constrained trenches and exhibit less deformation of delicate remaining structures. However, local plasmas may damage the substrate through the production of electric arcs as they discharge.

Thus, there is a need for improved systems and methods that can be used to produce high quality devices and structures. These and other needs are addressed by the present technology.

### SUMMARY

Exemplary methods of semiconductor processing may include forming plasma effluents of a plurality of precursors (e.g., an etchant precursor, an oxygen-containing precursor, and a silicon-and-fluorine-containing precursor). An example silicon-and-fluorine-containing precursor is silicon tetrafluoride. The plasma effluents may then contact a silicon-containing material and a mask material on a substrate in a processing region of a semiconductor processing chamber. More specifically, the silicon-containing material may be disposed on the substrate, and the mask material (e.g., a dielectric material) may be disposed on the silicon-containing material. The mask material may have one or more apertures therein that allow the plasma effluents access to the silicon-containing material. Contacting the silicon-containing material and the mask material with the plasma effluents may cause (i) etching the silicon-containing material with the plasma effluents to form and/or deepen one or more features in the silicon-containing material and (ii) simultaneously etching the mask material and depositing a silicon-and-oxygen-containing material on the mask material with the plasma effluents.

In some embodiments, the etchant precursor may include one or more of: a chlorine-containing precursor, a bromine-containing precursor, and a fluorine-containing precursor that is not silicon tetrafluoride. In some embodiments, a volumetric ratio of the oxygen-containing precursor relative to the silicon-and-fluorine-containing precursor may be less than or about 50:1. Further, a volumetric ratio of the etchant precursor relative to the oxygen-containing precursor may be less than or about 20:1. In some instances, a carrier gas may be present when forming plasma effluents, and a volumetric ratio of the carrier gas relative to the oxygen-containing precursor may be less than or about 10:1.

In some embodiments, the silicon-containing material may include one or more of: crystalline silicon, amorphous silicon, doped silicon, silicon nitride, silicon carbide, boron silicide, tungsten silicide, tungsten boron carbide, and silicon germanium. The semiconductor processing method may selectively remove the silicon-containing material relative to the mask material. For example, the semiconductor processing method may remove the silicon-containing material relative to the mask material at a selectivity greater than or about 4.

In some instances, the one or more apertures are characterized by a critical dimension of less than or about 1000 nm, or preferably less than or about 50 nm, such as 5 nm to 25 nm. After the etching of the silicon-containing material, the one or more features may be characterized by a depth of greater than or about 100 nm. After the etching of the silicon-containing material, the one or more features are characterized by an aspect ratio of greater than or about 5:1.

In some embodiments, a pressure in the processing region may be maintained at about 5 Torr or less. In some embodiments, a temperature in the processing region may be maintained at about 100° C. or less. In some embodiments, the plasma effluents may be generated at a plasma power of about 5000 W or less.

Some embodiments on the present technology may encompass semiconductor processing methods. The methods may include forming plasma effluents of a plurality of precursors (e.g., an etchant precursor, an oxygen-containing precursor, and a silicon-and-fluorine-containing precursor) in the presence of a carrier gas. An example silicon-and-fluorine-containing precursor is silicon tetrafluoride. A volumetric ratio of the oxygen-containing precursor relative to the silicon-and-fluorine-containing precursor may be less than or about 50:1; a volumetric ratio of the etchant precursor relative to the oxygen-containing precursor may be less than or about 20:1; and a volumetric ratio of the carrier gas relative to the oxygen-containing precursor may be less than or about 10:1. The plasma effluents may then contact a silicon-containing material and a mask material on a substrate in a processing region of a semiconductor processing chamber. More specifically, the silicon-containing material may be disposed on the substrate, and the mask material (e.g., a dielectric material) may be disposed on the silicon-containing material. The mask material may have one or more apertures therein that allow the plasma effluents access to the silicon-containing material. Contacting the silicon-containing material and the mask material with the plasma effluents may cause (i) etching the silicon-containing material with the plasma effluents to form and/or deepen one or more features in the silicon-containing material and (ii) simultaneously etching the mask material and depositing a silicon-and-oxygen-containing material on the mask material with the plasma effluents.

The semiconductor processing method may selectively remove the silicon-containing material relative to the mask material. For example, the semiconductor processing method may remove the silicon-containing material relative to the mask material at a selectivity greater than or about 4. In some instances, the one or more apertures are characterized by a critical dimension of less than or about 1000 nm, or preferably less than or about 50 nm, such as 5 nm to 25 nm. After the etching of the silicon-containing material, the one or more features may be characterized by a depth of greater than or about 100 nm. After the etching of the silicon-containing material, the one or more features are characterized by an aspect ratio of greater than or about 5:1.

Some embodiments on the present technology may encompass semiconductor processing methods. The methods may include forming plasma effluents of a plurality of precursors (e.g., an etchant precursor, an oxygen-containing precursor, and silicon tetrafluoride where a volumetric ratio of the oxygen-containing precursor relative to the silicon tetrafluoride is less than or about 50:1). The plasma effluents may then contact a silicon-containing material and a mask material on a substrate in a processing region of a semiconductor processing chamber. More specifically, the silicon-containing material may be disposed on the substrate, and the mask material (e.g., a dielectric material) may be disposed on the silicon-containing material. The mask material may have one or more apertures therein that allow the plasma effluents access to the silicon-containing material. Contacting the silicon-containing material and the mask material with the plasma effluents may cause (i) etching the silicon-containing material with the plasma effluents to form and/or deepen one or more features in the silicon-containing material and (ii) simultaneously etching the mask material and depositing a silicon-and-oxygen-containing material on the mask material with the plasma effluents.

In some embodiments, the plasma effluents may be first plasma effluents of a first plurality of precursors, and the method may further include forming second plasma effluents from a second plurality of precursors that do not include silicon tetrafluoride. The second plasma effluents may etch the silicon-containing material to form and/or deepen the one or more features in the silicon-containing material.

The semiconductor processing method may selectively remove the silicon-containing material relative to the mask material. For example, the semiconductor processing method may remove the silicon-containing material relative to the mask material at a selectivity greater than or about 4. In some instances, the one or more apertures are characterized by a critical dimension of less than or about 1000 nm, or preferably less than or about 50 nm, such as 5 nm to 25 nm. After the etching of the silicon-containing material, the one or more features may be characterized by a depth of greater than or about 100 nm. After the etching of the silicon-containing material, the one or more features are characterized by an aspect ratio of greater than or about 5:1.

Such technology may provide numerous benefits over conventional systems and techniques. For example, embodiments of the present technology may enhance the formation of and deepening of features in semiconductor structures. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary processing chamber according to some embodiments of the present technology.

FIG. 2 shows operations in a semiconductor processing method according to some embodiments of the present technology.

FIGS. 3A-3C show exemplary schematic cross-sectional structures produced according to some embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label with a letter that distinguishes among the similar components. If only the first reference label is used in the specification, the description applies to any one of the similar components having the same first reference label irrespective of the letter.

### DETAILED DESCRIPTION

As semiconductor structures decrease in size, the dimension of the features on said structures also decrease and often become more densely packed. Forming features on semiconducting structures can be achieved using a variety of methods including etching, which may use a mask material to protect an underlying silicon-containing material where apertures in the mask material allow for etching the underlying silicon-containing material in desired locations. Conventional technologies use plasma etching and masks to increase the depth of features on the semiconducting structures. However, the etchants can cause damage to the masks, which leads to features with irregular dimensions. Further, as the critical dimension (or width) at the opening of the feature decreases, reaction at the mask or top of the feature can more readily clog or plug the opening and hinder etchant access into the feature. One way to overcome this is a thicker mask where the cost and time to produce the mask increases with thickness.

The present technology overcomes these issues with a silicon-and-fluorine-containing precursor (e.g., silicon tetrafluoride). In plasma etching method, the silicon-and-fluorine-containing precursor can produce silicon-containing plasma effluents and fluorine-containing plasma effluents. As described in more detail herein, the silicon-containing plasma effluents may facilitate the regeneration of the mask material that is simultaneously being etched in the process. Cumulatively, this simultaneous action allows for minimal change in the thickness of the mask during the process of the present disclosure, which facilitates the use of thinner masks.

Further, the fluorine-containing plasma effluents have a relatively high electronegativity that allows the fluorine-containing plasma effluents to hinder the deposition of unwanted materials, especially at the opening of the feature, thereby mitigating clogging of the opening.

Although the remaining disclosure will routinely identify specific semiconductor processing methods utilizing the disclosed technology, and will describe one type of semiconductor processing chamber, it will be readily understood that the processes described may be performed in any number of semiconductor processing chambers. Accordingly, the technology should not be considered to be so limited as for use with these specific deposition processes or chambers alone. The disclosure will discuss one possible chamber that may be used to perform processes according to embodiments of the present technology before methods of semiconductor processing according to the present technology are described.

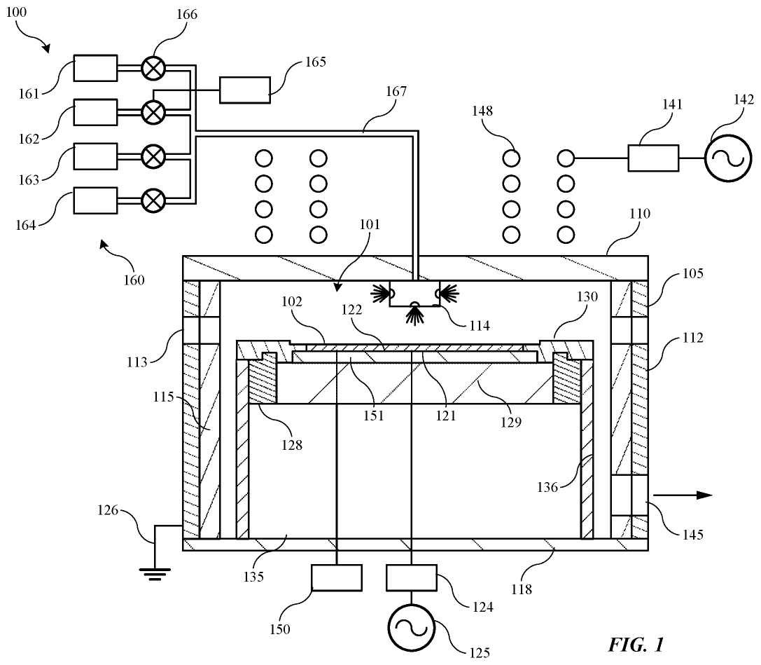

FIG. 1 illustrates a schematic cross-sectional view of an exemplary processing chamber 100 suitable for patterning a material layer disposed on a substrate 102 in the processing chamber 100. The exemplary processing chamber 100 is suitable for performing a patterning process, although it is to be understood that aspects of the present technology may be performed in any number of chambers, and substrate supports according to the present technology may be included in etching chambers, deposition chambers, treatment chambers, or any other processing chamber. The plasma processing chamber 100 may include a chamber body 105 defining a chamber volume 101 in which a substrate may be processed. The chamber body 105 may have sidewalls 112 and a bottom 118 which are coupled with ground 126. The sidewalls 112 may have a liner 115 to protect the sidewalls 112 and extend the time between maintenance cycles of the plasma processing chamber 100. The dimensions of the chamber body 105 and related components of the plasma processing chamber 100 are not limited and generally may be proportionally larger than the size of the substrate 102 to be processed therein. Examples of substrate sizes include 200 mm diameter, 250 mm diameter, 300 mm diameter and 450 mm diameter, among others, such as display or solar cell substrates as well.

The chamber body 105 may support a chamber lid assembly 110 to enclose the chamber volume 101. The chamber body 105 may be fabricated from aluminum or other suitable materials. A substrate access port 113 may be formed through the sidewall 112 of the chamber body 105, facilitating the transfer of the substrate 102 into and out of the plasma processing chamber 100. The access port 113 may be coupled with a transfer chamber and/or other chambers of a substrate processing system as previously described. A pumping port 145 may be formed through the sidewall 112 of the chamber body 105 and connected to the chamber volume 101. A pumping device may be coupled through the pumping port 145 to the chamber volume 101 to evacuate and control the pressure within the processing volume. The pumping device may include one or more pumps and throttle valves.

A gas panel 160 may be coupled by a gas line 167 with the chamber body 105 to supply process gases into the chamber volume 101. The gas panel 160 may include one or more process gas sources 161, 162, 163, 164 and may additionally include inert gases, non-reactive gases, and reactive gases, as may be utilized for any number of processes. Examples of process gases that may be provided by the gas panel 160 include, but are not limited to, hydrocarbon containing gas including methane, silicon tetrafluoride, sulfur hexafluoride, silicon chloride, carbon tetrafluoride, hydrogen bromide, hydrocarbon containing gas, argon gas, chlorine, nitrogen, helium, or oxygen gas, as well as any number of additional materials. Additionally, process gases may include nitrogen, chlorine, fluorine, oxygen, and hydrogen containing gases such as H₂, NH₃, H₂O, H₂O₂, NF₃, HF, F₂, CF₄, CHF₃, C₂F₆, C₂F₄, C₃F₆, C₄F₆, C₄F₈, BrF₃, ClF₃, SF₆, CH₃F, CH₂F₂, BCl₃, PF₃, PH₃, SO₂, and COS, among any number of additional precursors.

Valves 166 may control the flow of the process gases from the sources 161, 162, 163, 164 from the gas panel 160 and may be managed by a controller 165. The flow of the gases supplied to the chamber body 105 from the gas panel 160 may include combinations of the gases form one or more sources. The lid assembly 110 may include a nozzle 114. The nozzle 114 may be one or more ports for introducing the process gases from the sources 161, 162, 164, 163 of the gas panel 160 into the chamber volume 101. After the process gases are introduced into the plasma processing chamber 100, the gases may be energized to form plasma. An antenna 148, such as one or more inductor coils, may be provided adjacent to the plasma processing chamber 100. An antenna power supply 142 may power the antenna 148 through a match circuit 141 to inductively couple energy, such as RF energy, to the process gas to maintain a plasma formed from the process gas in the chamber volume 101 of the plasma processing chamber 100. Alternatively, or in addition to the antenna power supply 142, process electrodes below the substrate 102 and/or above the substrate 102 may be used to capacitively couple RF power to the process gases to maintain the plasma within the chamber volume 101. The operation of the power supply 142 may be controlled by a controller, such as controller 165, that also controls the operation of other components in the plasma processing chamber 100.

A substrate support pedestal 135 may be disposed in the chamber volume 101 to support the substrate 102 during processing. The substrate support pedestal 135 may include an electrostatic chuck 122 for holding the substrate 102 during processing. The electrostatic chuck (“ESC”) 122 may use the electrostatic attraction to hold the substrate 102 to the substrate support pedestal 135. The ESC 122 may be powered by an RF power supply 125 integrated with a match circuit 124. The ESC 122 may include an electrode 121 embedded within a dielectric body. The electrode 121 may be coupled with the RF power supply 125 and may provide a bias which attracts plasma ions, formed by the process gases in the chamber volume 101, to the ESC 122 and substrate 102 seated on the pedestal. The RF power supply 125 may cycle on and off, or pulse, during processing of the substrate 102. The ESC 122 may have an isolator 128 for the purpose of making the sidewall of the ESC 122 less attractive to the plasma to prolong the maintenance life cycle of the ESC 122. Additionally, the substrate support pedestal 135 may have a cathode liner 136 to protect the sidewalls of the substrate support pedestal 135 from the plasma gases and to extend the time between maintenance of the plasma processing chamber 100.

Electrode 121 may be coupled with a power source 150. The power source 150 may provide a chucking voltage of about 5000 volts to about −5,000 volts to the electrode 121. The power source 150 may also include a system controller for controlling the operation of the electrode 121 by directing a DC current to the electrode 121 for chucking and de-chucking the substrate 102. For example, similar to the RF power supply 125, power supply 150 may provide a bias which attracts plasma ions, formed by the process gases in the chamber volume 101, to the ESC 122 and substrate 102 seated on the pedestal. The power supply 150 may cycle on and off, or pulse, during processing of the substrate 102. In embodiments, the power supply 150 may supply RF power, DC current or voltage for chucking and/or bias, or a combination thereof. In additional embodiments, multiple power supplies may be configured to supply RF power and DC current or voltage for chucking and/or bias. The ESC 122 may include heaters disposed within the pedestal and connected to a power source for heating the substrate, while a cooling base 129 supporting the ESC 122 may include conduits for circulating a heat transfer fluid to maintain a temperature of the ESC 122 and substrate 102 disposed thereon. The ESC 122 may be configured to perform in the temperature range required by the thermal budget of the device being fabricated on the substrate 102. For example, the ESC 122 may be configured to maintain the substrate 102 at a temperature of about −150° C. or lower to about 500° C. or higher depending on the process being performed.

The cooling base 129 may be provided to assist in controlling the temperature of the substrate 102. To mitigate process drift and time, the temperature of the substrate 102 may be maintained substantially constant by the cooling base 129 throughout the time the substrate 102 is in the cleaning chamber. In some embodiments, the temperature of the substrate 102 may be maintained throughout subsequent cleaning processes at temperatures between about −150° C. and about 500° C., although any temperatures may be utilized. A cover ring 130 may be disposed on the ESC 122 and along the periphery of the substrate support pedestal 135. The cover ring 130 may be configured to confine etching gases to a desired portion of the exposed top surface of the substrate 102, while shielding the top surface of the substrate support pedestal 135 from the plasma environment inside the plasma processing chamber 100. Lift pins may be selectively translated through the substrate support pedestal 135 to lift the substrate 102 above the substrate support pedestal 135 to facilitate access to the substrate 102 by a transfer robot or other suitable transfer mechanism as previously described.

The controller 165 may be utilized to control the process sequence, regulating the gas flows from the gas panel 160 into the plasma processing chamber 100, and other process parameters. Software routines, when executed by the CPU, transform the CPU into a specific purpose computer such as a controller, which may control the plasma processing chamber 100 such that the processes are performed in accordance with the present disclosure. The software routines may also be stored and/or executed by a second controller that may be associated with the plasma processing chamber 100.

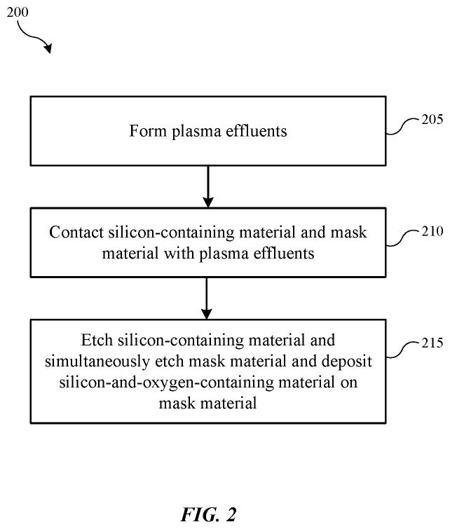

The chambers discussed previously may be used in performing exemplary methods including etching methods and treatment methods. Turning to FIG. 2 is shown exemplary operations in method 200 according to embodiments of the present technology. Before the first operation of the method, a substrate may be processed in one or more ways (e.g, front-end processing, deposition, etching, polishing, cleaning, or any other operation) before being placed within a processing region of a chamber in which method 200 may be performed. Some or all of these operations may be performed in chambers or system tools as previously described or may be performed in different chambers on the same system tool, which may include the chamber in which the operations of method 200 are performed.

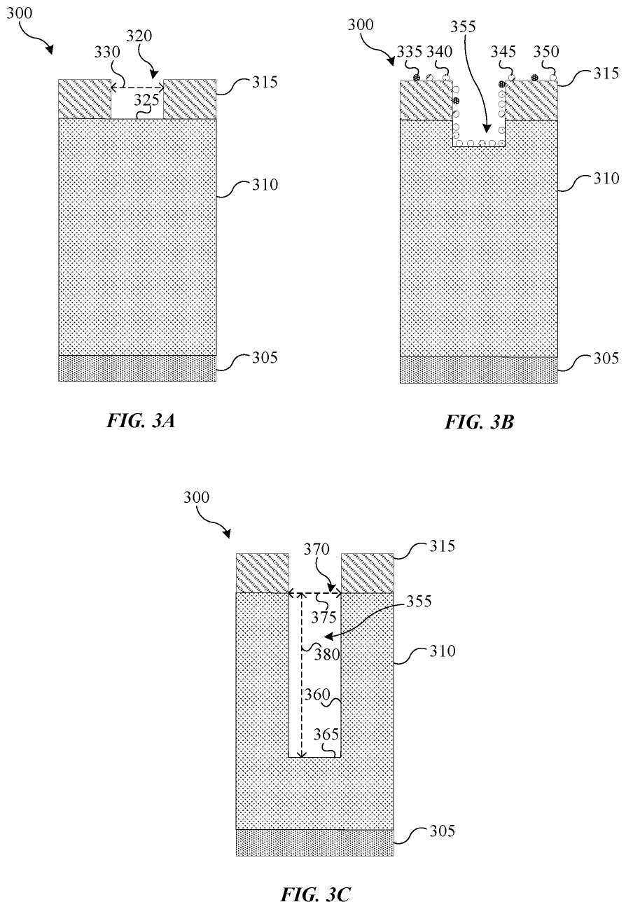

Method 200 may include several optional operations, which may or may not be specifically associated with some embodiments of methods according to the present technology. For example, many of the operations are described to provide a broader scope of the structural formation but are not critical to the technology or may be performed by alternative methodology as will be discussed further below. Method 200 describes operations shown schematically in FIGS. 3A-3C, the illustrations of which will be described in conjunction with the operations of method 200. It is to be understood that FIGS. 3A-3B illustrates only partial schematic views, and a substrate may contain any number of structural sections having aspects as illustrated in the figures, as well as alternative structural aspects that may still benefit from operations of the present technology.

Method 200 may or may not involve optional operations to develop the semiconductor structure 300 to a particular fabrication operation. It is to be understood that method 200 may be performed on any number of semiconductor structures 300, and FIG. 3A illustrates one exemplary structure within which a contact cleaning or etching process may be performed. As illustrated in FIG. 3A, a processed semiconductor structure 300 may include a substrate 305 having a silicon-containing material 310 disposed thereon, which itself has a patterned mask material 315 disposed thereon. Substrate 305 may be or may include a dielectric material, such as an oxide or nitride of any number of materials. For example, the silicon-containing material 310 may be or may include crystalline silicon, amorphous silicon, doped silicon, silicon nitride, silicon carbide, boron silicide, tungsten silicide, tungsten boron carbide, silicon germanium, or any combination thereof.

Although mask material 315 is illustrated as a single layer of material, the mask material 315 may include one or more layers of material. The mask material 315 may be a hardmask, a photoresist mask, or a combination thereof. For example, the mask material 315 may include a hardmask having a photoresist mask disposed thereon. Alternatively, the mask material 315 may include only a hardmask. The hardmask may be composed of one or more layers (e.g., up to 10 layers) of material. Individual layers of a hardmask may include materials like silicon, silicon oxide, silicon nitride, silicon oxynitride, silicon carbide, amorphous carbon, or any combination thereof. The mask material 315 may be or include a patterned photoresist layer, such as a lithographically patterned mask or fabricated by other materials. The photoresist layer may be a positive tone photoresist, a negative tone photoresist, a UV lithography photoresist, an i-line photoresist, an e-beam resist (for example, a chemically amplified resist (CAR)), or another suitable photoresist. The mask may be characterized by a thickness of less than or about 2000 nm, such as 10 nm to 2000 nm, 10 nm to 500 nm, 50 nm to 1000 nm, 500 nm to 1500 nm, or 1000 nm to 2000 nm.

The mask material 315 may be patterned to form apertures 320 through the mask material 315 that exposes portions 325 of underlying silicon-containing material 310. The aperture 320 may be characterized by a critical dimension 330 (or width of the aperture 320) of less than or about 1000 nm, such as 5 nm to 1000 nm, 5 nm to 25 nm, 5 nm to 50 nm, 10 nm to 20 nm, 50 nm to 250 nm, 50 nm to 500 nm, 250 nm to 750 nm, or 500 nm to 1000 nm. It is to be understood that the noted structure is not intended to be limiting, and any of a variety of other semiconductor structures are similarly encompassed. While the methods 200 of the present disclosure may be applicable to small and large apertures, advantageously, the methods of the present disclosure are relevant to apertures with a small critical dimension 330 of less than or about 50 nm, such as 5 nm to 50 nm, 5 nm to 25 nm, 10 nm to 20 nm, or 25 nm to 50 nm. Other exemplary structures may include two-dimensional and three-dimensional structures common in semiconductor manufacturing, and within which a silicon-containing material is to be removed.

Method 200 may include forming plasma effluents 335, 340, 345, and 350 of a plurality of precursors that comprise a silicon-and-fluorine-containing precursor, an etchant precursor, and an oxygen-containing precursor in operation 205. For example, the silicon-and-fluorine-containing precursor may include silicon tetrafluoride (SiF₄). For example, the etchant precursor may include one or more materials including a chlorine-containing precursor, a bromine-containing precursor, or a fluorine-containing precursor. For example, the chlorine-containing precursor may include one or more materials including diatomic chlorine (Cl₂) or hydrogen chloride (HCl). For example, the bromine-containing precursor may include hydrogen bromide (HBr). For example, the fluorine-containing precursor may include one or more materials including nitrogen trifluoride (NF₃), hydrogen fluoride (HF), diatomic fluorine (F₂), carbon tetrafluoride (CF₄), trifluoromethane (CHF₃), hexafluoroethane (C₂F₆), hexafluoropropylene (C₃F₆), bromine trifluoride (BrF₃), chlorine trifluoride (ClF₃), sulfur hexafluoride (SF₆), additional fluorine-substituted hydrocarbons, or fluorine-containing materials. For example, the oxygen-containing precursor may include one or more materials including oxygen (O₂), carbon dioxide (CO₂), carbon monoxide (CO), nitrous oxide (N₂O), nitrogen dioxide (NO₂), ozone (O₃), or water (H₂O).

The precursors may also include any number of carrier gases, which may include nitrogen, helium, argon, or other noble, inert, or useful precursors. The carrier gases may be used to dilute the precursors, which may further reduce etching rates and/or allow adequate diffusion through the aperture 320.

The plasma effluents 335, 340, 345, and 350 formed from the precursors may be formed locally in the processing region or in a remote plasma system. That is, the plasma effluents 335, 340, 345, and 350 may be produced in the processing region of the semiconductor processing chamber housing the semiconductor structure 300. Alternatively, the plasma effluents 335, 340, 345, and 350 may be produced remotely and provided to the processing region of the semiconductor processing chamber housing the semiconductor structure 300. For example, the plasma treatment may be generated by a remote plasma source (RPS), a capacitively coupled plasma (CCP), or an inductively coupled plasma (ICP) with or without one or more carrier gases such as argon (Ar), helium (He), NH₃, nitrogen (N₂), H₂, or mixtures thereof. The plasma effluents 335, 340, 345, 350 may be a low-level plasma to limit the amount of bombardment, sputtering, and surface modification. In embodiments, the plasma power may be less than or about 5,000 W, less than or about 4,500 W, less than or about 4,000 W, less than or about 3,500 W, less than or about 3,000 W, less than or about 2,500 W, less than or about 2,000 W, less than or about 1,500 W, less than or about 1,000 W, less than or about 750 W, less than or about 500 W, or less, although the plasma power may also be included in ranges between any two of these stated numbers or within any smaller range encompassed by any of the stated ranges. By utilizing a low-level plasma power, the plasma effluents 335, 340, 345, 350 may be better controlled for delivery through the apertures 320 of the mask material 315, while limiting sputtering of the mask material 315 as well as other exposed surfaces.

Method 200 may include contacting the silicon-containing material 310 and the mask material 315 with the plasma effluents 335, 340, 345, 350 in the processing region of the semiconductor processing chamber at operation 210. As illustrated in FIG. 3B, the contacting of the silicon-containing material 310 with the plasma effluents 335, 340, 345, 350 may cause etching of the silicon-containing material 310, which may form and/or deepen features 355 in the silicon-containing material 310, at operation 215. Further, contacting of the mask material 315 with the plasma effluents 335, 340, 345, 350 may cause simultaneous etching of the mask material 315 and deposition of a silicon-and-oxygen-containing material on the mask material 315, at operation 215.

Without being limited by theory, it is believed that the silicon-containing plasma effluents 335 from the silicon-and-fluorine-containing precursor (e.g, silicon tetrafluoride) and oxygen-containing plasma effluents 345 from the oxygen-containing precursor may cause deposition of a silicon-and-oxygen-containing material on the mask material 315. Simultaneously, the plasma effluents 350 from the etchant precursor and/or the silicon-and-fluorine-containing precursor may etch the mask material 315 as well as the silicon-containing material 350. The fluorine-containing plasma effluents 340 from the etchant precursor and/or silicon-and-fluorine-containing precursor (e.g, silicon tetrafluoride) may preferentially contact the silicon-containing material because of a higher electronegativity relative to the other plasma effluents 335, 345, 350 (especially the oxygen-containing plasma effluents 345 from the oxygen-containing precursor and the silicon-containing plasma effluents 335 from the silicon-and-fluorine-containing precursor). By preferentially contacting the silicon-containing material 310, the fluorine-containing plasma effluents 340 may mitigate the formation of silicon-and-oxygen-containing material on the silicon-containing material 310, which could reduce the width (or critical dimension) of the features 355, especially near the interface between the mask material 315 and the silicon-containing material 310. A reduction in the width of the features would reduce access of the plasma effluents 350 from the etchant precursor to the features 355, which would reduce etching of the silicon-containing material 310 that deepens the features 355. Therefore, the mask material 315 may be simultaneously etched and replenished (via the deposition) while the silicon-containing material 310 may be etched, which results in the silicon-containing material 310 being selectively removed relative to the mask material 315. Advantageously, the method 200 of the present disclosure may result in minimal change in the thickness of the mask material 315 while still forming deep features 355, which may allow for a thinner mask material 315 at the beginning of the method.

While the illustrated method 200 and semiconductor structure 300 illustrate forming the features 355 using plasma effluents 335, 340 from the silicon-and-fluorine-containing precursor, in alternate embodiments, the feature 355 may already be formed (or started) and the plasma effluents 335, 340 from the silicon-and-fluorine-containing precursor may be used in only deepening the features 355. For example, the method may include forming first plasma effluents from first precursors comprising first etchant precursors; contacting the mask material and the silicon-containing material with the first plasma effluents to cause etching of the silicon-containing material that forms and deepens the features (e.g., deepens by about 5 nm to 100 nm); then forming second plasma effluents from second precursors comprising the silicon-and-fluorine-containing precursors, the oxygen-containing precursors, and second etchant precursors (which may be the same or different than the first etchant precursors); and contacting the silicon-containing material and the mask material with the second plasma effluents to cause etching of the silicon-containing material to deepen the features and simultaneous etching of and deposition on the mask material as described herein.

The silicon-containing material 310 may define sidewalls 360 and a bottom 365 of the features 355 and each of the apertures 320 defines an opening 370 at the top of each of features 355 where the mask material 315 interfaces with the silicon-containing material 310. After completion of method 200 illustrated in FIG. 3C, the features 355 may be characterized by a critical dimension 375 at the opening 370 at the top of the features 355, a depth 380 from the opening 370 to the bottom 365 of the features 355, an aspect ratio (depth 380 relative to critical dimension 375), or any combination thereof. After completion of method 200, the features 355 may be characterized by a critical dimension 375 of less than or about 1000 nm, such as 5 nm to 1000 nm, 5 nm to 25 nm, 5 nm to 50 nm, 10 nm to 20 nm, 50 nm to 250 nm, 50 nm to 500 nm, 250 nm to 750 nm, or 500 nm to 1000 nm, and preferably less than or about 50 nm, such as 5 nm to 50 nm, 5 nm to 25 nm, 10 nm to 20 nm, or 25 nm to 50 nm. After completion of method 200, the feature 355 may be characterized by a depth 380 of greater than or about 100 nm, such as 100 nm to 50,000 nm, 100 nm to 1000 nm, 500 nm to 5000 nm, 1000 nm to 10,000 nm, or 5000 nm to 50,000 nm. After completion of method 200, the feature 355 may be characterized by an aspect ratio of greater than or about 5:1, such as greater than or about 10:1, greater than or about 15:1, greater than or about 20:1, greater than or about 25:1, greater than or about 30:1, greater than or about 35:1, greater than or about 40:1, greater than or about 45:1, greater than or about 50:1, greater than or about 60:1, greater than or about 70:1, greater than or about 80:1, greater than or about 90:1, greater than or about 100:1, or more, or 5:1 to 200:1, 5:1 to 50:1, 25:1 to 100:1, 50:1 to 200:1, or more.

The mask material 315 before contacting with the plasma effluents may be characterized by a thickness of less than or about 2000 nm, such as 10 nm to 2000 nm, 10 nm to 500 nm, 50 nm to 1000 nm, 500 nm to 1500 nm, or 1000 nm to 2000 nm. After operations 210 and 215, the mask material 315 may be characterized by a thickness of less than or about 2000 nm, such as 10 nm to 2000 nm, 10 nm to 500 nm, 50 nm to 1000 nm, 500 nm to 1500 nm, or 1000 nm to 2000 nm. Comparing the mask material 315 thickness before and after operations 210 and 215, the mask material 315 may be characterized by a thickness change of less than or about 200 nm, such as 0 nm to 10 nm, 0 nm to 20 nm, 1 nm to 50 nm, 25 nm to 100 nm, or 50 nm to 200 nm. The thickness of the mask material 315 after operations 210 and 215 may depend on a variety of factors include, but not limited to, the precursor gas ratios, the applied RF power(s), the chamber pressure, and the like.

The method 200 may be characterized by preferential (or selective) removal of the silicon-containing material 310 relative to the mask material 315. Selectively is defined as the depth 380 of the feature 355 divided by the difference between a starting thickness of the mask material 315 (MTs) and a final thickness of the mask material 315 (MTF), which is shown in the below formula.

$$Selectivity = Feature Depth / ( {MT}_{S} - {MT}_{F} )$$

For example, a method 200 may be performed where (i) in FIG. 3A before etching, the mask material 315 may have a thickness of 100 nm and (ii) in FIG. 3C after etching, the mask material 315 may have a thickness of 60 nm and the feature 355 may have a depth 380 of 300 nm. In said example, the selectivity removal of the silicon-containing material 310 relative to the mask material 315 would be 300 nm/(100 nm-60 nm)=7.5. The method 200 may be characterized by a selectivity for removing the silicon-containing material 310 relative to the mask material 315 of greater than or about 4, such as greater than or about 6, greater than or about 8, greater than or about 10, greater than or about 12, greater than or about 14, greater than or about 16, greater than or about 18, greater than or about 20, or greater than or about 22, or more, or 4 to 30, 4 to 15, 10 to 20, or 15 to 30. The selectivity may depend on a variety of factors including, but not limited to, precursor gas ratios, RF power(s), chamber pressure, and the like.

During operation 205, the volumetric ratio of the oxygen-containing precursors relative to the silicon-and-fluorine-containing precursors may be less than or about 50:1, such as 10:1 to 50:1, 10:1 to 30:1, 15:1 to 40:1, or 20:1 to 50:1. Without being limited by theory, it is believed that increased SiF₄ flow relative to O₂ flow (i.e., lower volumetric ratios of the oxygen-containing precursors relative to the silicon-and-fluorine-containing precursors) may lead to increased mask deposition resulting in increased clogging. However, there may be an inflection point in the O₂:SiF₄ volumetric ratio where there is not enough O₂ to support increased deposition and mask material deposition rate decreases.

During operation 205, the volumetric ratio of the etchant precursors relative to the oxygen-containing precursors may be less than or about 20:1, such as 1:1 to 20:1, or 1:1 to 15:1, or 5:1 to 20:1. Without being limited by theory, oxygen-containing precursors like O₂ act as both a precursor for mask material deposition (in conjunction with SiF₄) as well as a precursor for passivation for the sidewalls 360 of the features 355. While reduced oxygen-containing precursors (i.e., higher volumetric ratio of the etchant precursors relative to the oxygen-containing precursors) are believed to result in reduced clogging, it may likely also result in enlarged feature widths and increased feature bowing. The appropriate volumetric ratio of the etchant precursors relative to the oxygen-containing precursors may be highly dependent on the composition of the silicon-containing material 310. Therefore, clogging may be more effectively controlled or mitigated by the amount of silicon-and-fluorine-containing precursors used (i.e., the volumetric ratio of the oxygen-containing precursors relative to the silicon-and-fluorine-containing precursors as opposed to the volumetric ratio of the etchant precursors relative to the oxygen-containing precursors).

During operation 205, the volumetric ratio of the carrier gas (e.g., nitrogen, helium, argon) relative to the oxygen-containing precursors may be less than or about 10:1, such as 1:1 to 10:1, 1:1 to 5:1, 3:1 to 7:1, or 5:1 to 10:1. Without being limited by theory, it is believed that most inert carrier gasses have minimal impact to overall process performance and serve to dilute highly electro-negative plasmas, providing increased plasma stability by reducing the observed reflected power in the RF system. However, diatomic inert gasses (e.g., N₂) may have significant impacts on plasma chemistry by increasing the fluorine signal (observed in optical emission spectroscopy) resulting in reduced selectivity and increased mask damage.

During any operation 205, 210, and/or 215 of method 200, a bias power may be applied to the substrate 305. The bias power may provide a directional flow of plasma effluents to the substrate 305. Thus, the etchants may be directed into the apertures 320, which may facilitate the plasma effluents to progress through the materials being etched and reach the substrate 305. In embodiments, the plasma power may be greater than or about 500 W and may be greater than or about 750 W, greater than or about 1,000 W, greater than or about 1,500 W, greater than or about 2,000 W, greater than or about 2,500 W, greater than or about 2,750 W, greater than or about 3,000 W, greater than or about 3,250 W, greater than or about 3,500 W, greater than or about 4,000 W, greater than or about 4,500 W, greater than or about 5,000 W, or more, although the bias power may also be included in ranges between any two of these stated numbers or within any smaller range encompassed by any of the stated ranges. By applying a bias power, narrow ion angle distribution may result and provide better profile control (e.g., without bending and/or twisting) and verticality of the etching. The narrow ion angle distribution may reduce sidewall attack, increase the etch rate, and make the etch front more square.

In embodiments, the bias power may be applied via an RF power supply, such as RF power supply 125, and/or a power supply used for directing DC current or voltage to the ESC, such as power supply 150. As previously discussed with regard to FIG. 1, the RF power supply and/or the power supply used for directing DC current or voltage may cycle on and off, or pulse, during processing. By pulsing, ion energy, and ion flux may be better controlled, and lower angular spread of the plasma effluents may be achieved. Additionally, the pulsing may neutralize a charge of the plasma effluents at the etch front, which may increase the uniformity of the etch. In embodiments where the bias power is applied by both the RF power supply and the power supply used for directing DC current or voltage to the ESC, the power supplies may be synchronized or non-synchronized. The DC current or voltage may be pulsed at the micro-second scale and may be characterized by duty cycle between 0% and 100%. In some embodiments, an additional electrode may be present in the ESC for the pulsed DC current or voltage, whereas other embodiments may utilize the same electrode for both chucking and pulsing. In some embodiments, RF and pulsed DC may be supplied to only the cooling base 129, while a separate DC chucking power supply 150 may be connected to the chucking electrode (mesh) within the ceramic ESC.

Each of the operations of method 200 may be performed during a constant temperature in embodiments, while in some embodiments the temperature may be adjusted during different operations. For example, the substrate, pedestal, or chamber temperature during method 300 may be maintained at a temperature less than or about 100° C., less than or about 80° C., less than or about 60° C., less than or about 40° C., less than or about 20° C., less than or about 0° C., and in some embodiments the temperature may be maintained less than or about −20° C., less than or about −40° C., less than or about −50° C., less than or about −60° C., less than or about-70° C., less than or about −80° C., less than or about −90° C., less than or about −100° C., less than or about −110° C., less than or about −120° C., or less, although the temperature may also be included in ranges between any two of these stated numbers or within any smaller range encompassed by any of the stated ranges.

The pressure within the processing chamber may be controlled during method 300. For example, while forming the plasma effluents and contacting materials with the plasma effluents, the pressure within the semiconductor processing chamber may be maintained below or about 5 Torr. Additionally, in embodiments, the pressure within the semiconductor processing chamber may be maintained below or about 4 Torr, below or about 3 Torr, below or about 2 Torr, below or about 1 Torr, below or about 500 mTorr, below or about 250 mTorr, below or about 200 mTorr, below or about 150 mTorr, below or about 100 mTorr, below or about 80 m Torr, below or about 60 mTorr, below or about 50 mTorr, below or about 45 mTorr, below or about 40 mTorr, below or about 35 mTorr, below or about 30 mTorr, below or about 25 mTorr, below or about 20 mTorr, below or about 15 mTorr, below or about 10 mTorr, or less, although the pressure may also be included in ranges between any two of these stated numbers or within any smaller range encompassed by any of the stated ranges. The pressure within the processing chamber may affect the capabilities of flow into the aperture. For example, as pressure increases, plasma effluents may have increased difficulty in permeating the aperture 320 to reach the silicon-containing material 310. Accordingly, in some embodiments, the pressure may be maintained below or about 1 Torr to allow effluent flow into the aperture 320 and the feature 355 being etched in the silicon-containing material 310 on the substrate 305.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
i) forming plasma effluents of a plurality of precursors comprising an etchant precursor, an oxygen-containing precursor, and a silicon-and-fluorine-containing precursor, wherein the silicon-and-fluorine-containing precursor comprises silicon tetrafluoride;
ii) contacting a silicon-containing material and a mask material with the plasma effluents in a processing region of a semiconductor processing chamber, wherein a substrate is disposed on a substrate support within the processing region, wherein the silicon-containing material is disposed on the substrate and the mask material is disposed on the silicon-containing material, wherein the mask material has one or more apertures therein that allow the plasma effluents access to the silicon-containing material, wherein the mask material comprises a dielectric material;
iii) etching the silicon-containing material with the plasma effluents to form and/or deepen one or more features in the silicon-containing material; and
iv) simultaneously etching the mask material and depositing a silicon-and-oxygen-containing material on the mask material with the plasma effluents.

2. The semiconductor processing method of claim 1, wherein the etchant precursor comprises one or more of: a chlorine-containing precursor, a bromine-containing precursor, and a fluorine-containing precursor that is not silicon tetrafluoride.

3. The semiconductor processing method of claim 1, wherein a volumetric ratio of the oxygen-containing precursor relative to the silicon-and-fluorine-containing precursor is less than or about 50:1.

4. The semiconductor processing method of claim 1, wherein a volumetric ratio of the etchant precursor relative to the oxygen-containing precursor is less than or about 20:1.

5. The semiconductor processing method of claim 1, wherein a carrier gas is present when forming plasma effluents.

6. The semiconductor processing method of claim 5, wherein a volumetric ratio of the carrier gas relative to the oxygen-containing precursor is less than or about 10:1.

7. The semiconductor processing method of claim 1, wherein silicon-containing material comprises one or more of: crystalline silicon, amorphous silicon, doped silicon, silicon nitride, silicon carbide, boron silicide, tungsten silicide, tungsten boron carbide, and silicon germanium.

8. The semiconductor processing method of claim 1, wherein the method selectively removes the silicon-containing material relative to the mask material.

9. The semiconductor processing method of claim 1, wherein the method removes the silicon-containing material relative to the mask material at a selectivity greater than or about 4.

10. The semiconductor processing method of claim 1, wherein one or more apertures are characterized by a critical dimension of less than or about 1000 nm.

11. The semiconductor processing method of claim 1, wherein after the etching of the silicon-containing material, the one or more features are characterized by a depth of greater than or about 100 nm.

12. The semiconductor processing method of claim 1, wherein after the etching of the silicon-containing material, the one or more features are characterized by an aspect ratio of greater than or about 5:1.

13. The semiconductor processing method of claim 1, wherein a pressure in the processing region is maintained at about 5 Torr or less.

14. The semiconductor processing method of claim 1, wherein a temperature in the processing region is maintained at about 100° C. or less.

15. The semiconductor processing method of claim 1, wherein the plasma effluents are generated at a plasma power of about 5000 W or less.

16. A semiconductor processing method comprising:
i) forming plasma effluents of a plurality of precursors in the presence of a carrier gas, wherein the plurality of precursors comprises an etchant precursor, an oxygen-containing precursor, and a silicon-and-fluorine-containing precursor, wherein the silicon-and-fluorine-containing precursor comprises silicon tetrafluoride, wherein a volumetric ratio of the oxygen-containing precursor relative to the silicon-and-fluorine-containing precursor is less than or about 50:1, wherein a volumetric ratio of the etchant precursor relative to the oxygen-containing precursor is less than or about 20:1, wherein a volumetric ratio of the carrier gas relative to the oxygen-containing precursor is less than or about 10:1;
ii) contacting a silicon-containing material and a mask material with the plasma effluents in a processing region of a semiconductor processing chamber, wherein a substrate is disposed on a substrate support within the processing region, wherein the silicon-containing material is disposed on the substrate and the mask material is disposed on the silicon-containing material, wherein the mask material has one or more apertures therein that allow the plasma effluents access to the silicon-containing material, wherein the mask material comprises a dielectric material;
iii) etching the silicon-containing material with the plasma effluents to form and/or deepen one or more features in the silicon-containing material, wherein the silicon-containing material defines sidewalls and a bottom of the one or more features along the substrate and each of the one or more apertures defines an opening at a top of each of the one or more features; and
iv) simultaneously etching the mask material and depositing a silicon-and-oxygen-containing material on the mask material with the plasma effluents, wherein the method selectively removes the silicon-containing material relative to the mask material.

17. The semiconductor processing method of claim 16, wherein the method removes the silicon-containing material relative to the mask material at a selectivity greater than or about 4.

18. A semiconductor processing method comprising:
i) forming plasma effluents of a plurality of precursors comprising an etchant precursor, an oxygen-containing precursor, and silicon tetrafluoride, wherein a volumetric ratio of the oxygen-containing precursor relative to the silicon tetrafluoride is less than or about 50:1;
ii) contacting a silicon-containing material and a mask material with the plasma effluents in a processing region of a semiconductor processing chamber, wherein a substrate is disposed on a substrate support within the processing region, wherein the silicon-containing material is disposed on the substrate and the mask material is disposed on the silicon-containing material, wherein the mask material has one or more apertures therein that allow the plasma effluents access to the silicon-containing material, wherein the mask material comprises a dielectric material;
iii) etching the silicon-containing material with the plasma effluents to deepen one or more features in the silicon-containing material, wherein the silicon-containing material defines sidewalls and a bottom of the one or more features along the substrate and each of the one or more apertures defines an opening at a top of each of the one or more features; and
iv) simultaneously etching the mask material and depositing a silicon-and-oxygen-containing material on the mask material with the plasma effluents, wherein the method selectively removes the silicon-containing material relative to the mask material.

19. The semiconductor processing method of claim 18, wherein the plasma effluents are first plasma effluents of a first plurality of precursors, and wherein the method further comprises:
forming second plasma effluents from a second plurality of precursors that do not include silicon tetrafluoride; and
etching the silicon-containing material with the second plasma effluents to form and/or deepen the one or more features in the silicon-containing material.

20. The semiconductor processing method of claim 18, wherein the method removes the silicon-containing material relative to the mask material at a selectivity greater than or about 4.
